(19) United States
(12) Patent Application Publication
(10) Pub. No.: US 2008/0309200 A1
(43) Pub. Date: Dec. 18, 2008

(54) Ultrasonic Transducer Module Comprising a Transmitter Layer and a Receiver Layer

(75) Inventors: Terje Melandso, Brumunddal (NO); Frank Melandso, Kvaloysletta (NO); Tore Baarstad, Lillehammer (NO)

Correspondence Address: CHRISTIAN D. ABEL, ONSAGERS AS, POSTBOKS 6963 ST. OLAVS PLASS, NORWAY, N-0130, NO

(73) Assignee: DOLPHISCAN AS, Moelv (NO)

(21) Appl. No.: 12/094,996

(22) PCT Filed: Nov. 15, 2006
(86) PCT No.: PCT/NO06/00418

§ 371 Date: Aug. 26, 2008

Related U.S. Application Data
(60) Provisional application No. 60/740,265, filed on Nov. 29, 2005.

(30) Foreign Application Priority Data
Nov. 29, 2005 (GB) 0524307.6

(51) Int. Cl. H01L 41/083

(52) U.S. Cl. 310/334

(57) ABSTRACT

Ultrasonic transducer module comprises at least one transmitter layer, at least one receiver layer and at least one ground plane. The transmitter layer and the receiver layer comprise a number of elongated transmitter and receiver electrodes, the electrodes being arranged in parallel within each layer, the transmitter layers and the receiver layers are parallel, and the electrodes of the receiver layers make an angle greater than zero with the electrodes of at least one of the transmitter.

The invention regards an ultrasonic transducer module for sending and detecting an ultrasonic signal.

Ultrasonic transducers are used in a number of applications, such as in medicine, non-destructive testing, etc.

In many such applications, there is need for a sending and receiving the ultrasound signal with a certain degree of positional accuracy and signal/noise-ratio. There is also a need for a transducer which is simple to produce, has low material costs and is thus cost-effective.

U.S. Pat. No. 4,448,075 describes an ultrasonic scanning apparatus which utilizes a number of elongated, parallel driving line electrodes arranged on one surface of a transducer plate and a plurality of parallel grounding line electrodes arranged on the opposite surface of the transducer plate. The driving line electrodes and the grounding line electrodes intersect to effectively form a matrix of individual transducer elements capable of emitting and receiving ultrasonic beams. The emission and reception of ultrasonic beams must be done in separate operations by switching the driving electrodes between a transmit state and a receive state.

U.S. Pat. No. 5,209,126 describes a force sensor comprising a deformable medium having a contact surface against which a force can be applied, and uses the emission and reception of an ultrasound signal to measure the change in thickness of the deformable medium due to the applied force. The sensor comprises both a signal generator and signal receptor, and is able to both generate and receive the ultrasonic signals generally simultaneously.

The object of the invention is to provide an ultrasonic transducer module which is compact, simple, and easy to produce, and which provides a high resolution with a low number of contact points.

The object of the invention is achieved by means of the features of the patent claims.

An ultrasonic transducer module according to the invention comprises at least one transmitter layer, at least one receiver layer and means acting as ground plane, where the transmitter layer and the receiver layer comprise a number of elongated electrodes, the electrodes being arranged in parallel within each layer, the transmitter layers and the receiver layers are parallel, and the electrodes of the receiver layers make an angle greater than zero with the electrodes of at least one of the transmitter layers.

The transmitter layer is the signal generating layer of the transducer, which generates the ultrasound signal. The transmitter layer comprises a number of elongated transmitter electrodes stretching over most of or the full length of the transducer. The electrodes are arranged in parallel, i.e. the longitudinal directions of the electrodes are parallel, within each layer. When the word “parallel” is used in this disclosure, it is meant that the items are completely or nearly parallel.

In the simplest embodiment, the electrodes are of rectangular shape. The electrodes may however have other suitable shapes such as elongated with varying width. The wider sections/portions in such an embodiment may for example be circular, hexagonal, square or any other suitable shape. The choice of different geometries of the electrodes may lead to different sound distribution from the transmitter layer, and the shape of the electrodes may be chosen according to specific applications. By choosing a suitable shape and separation distance of the widened sections, a closer packing of the electrodes in the layer may be achieved and/or less gaps will be present between the active elements of the transducer.

The electrodes are in one embodiment designed in one single piece, and each single electrode comprises electric connecting means for connecting to signal generation means. In other embodiments, the electrodes may comprise a number of electrode portions, each portion having its own electric connecting means.

The transmitter layer further comprises a piezoelectric material. This material generates the sound waves when exposed to an alternating externally applied voltage. The piezoelectric material may be of any suitable kind, such as ceramic materials, crystals, polymers, etc. The polymer polyvinylidene fluoride (PVDF) is a piezoelectric material commonly used in transducers.

The transmitter electrodes may be provided directly on the surface of the piezoelectric material, for example by imprinting with lithography. In the preferred embodiment of the invention, the electrodes of at least one of the transmitter layers and/or receiver layers are provided on a flexible circuit. The flexible circuit is then connected/bonded to the piezoelectric material, for example by gluing. If an adhesive layer is used, it should preferably be applied very thin (e.g. in the size of 0.5-5 microns), in order to minimize reduction in electric field. The layer should also preferably be homogenous and not comprise any air voids.

An example on a flexible circuit is made of a Kapton® film. A flexible circuit has the advantages that the electrodes are easily produced on the board and connects well to the board. Because of the flexibility of the printed circuit board, there is a much reduced risk for breaking the electrode lines after production. The connection portions of the electrodes of a flexible circuit may be produced integrated in the board, and may be provided as standard connectors, which simplifies assembly and makes the connection points less vulnerable. The connections can also be made small of size. This means that when using a flexible circuit, it is possible to provide a higher number of connections than when imprinting the electrodes directly onto the piezoelectric material, and enables thus a higher number of electrodes on the same area, i.e. higher density of electrodes on the transducer. In the embodiments where the electrodes comprises a number of electrode sections, it is possible to provide the flexible circuits with internal conductors for connecting electrode sections not facing an edge of the flexible board to connecting means at the edges.

A flexible circuit has an etched conductor pattern (usually copper) on one side of dielectric base film. A dielectric covering, such as soldermask or coverlayer is usually applied to protect the conductors and define component placement areas

In order to achieve best possible transducer performance for the invention, the use of flexible circuit may include a special design, for example custom design of solder masks or coverlayers, or removal of cover layers for all or part of the flexible circuit.

The receiver layer is the signal receiving layer of the transducer. The signal receiving layer experiences an incoming ultrasound wave, and generates an electric signal according to this. The receiver layer comprises a number of elongated receiver electrodes stretching over most of or the full length of the transducer. As for the transmitter layer, the electrodes of the receiver layer are arranged in parallel within each layer. The shape and arrangement of the receiver electrodes within the receiver layer is similar to the transmitter electrodes, and the description of the transmitter electrodes is valid also for the receiver electrodes.

The receiver electrodes are in one embodiment designed in one single piece, and each single electrode comprises electric connecting means for connecting to signal processing means. In other embodiments, the electrodes may comprise a number of electrode portions, each portion having its own electric connecting means.

The receiver layer also comprises a piezoelectric material analogue to the transmitter layer. The piezoelectric material generates a voltage when experiencing deformations due to the sound waves of the ultrasound signal. This voltage signal is processed to get the information wanted from the transducer.

The receiver electrodes may be provided directly on the piezoelectric material, or be provided on a flexible circuit in the same way as described above for the transmitter electrodes. In one embodiment, transmitter electrodes and receiver electrodes are provided on each side of a flexible circuit. This embodiment is advantageous with respect to alignment of the electrodes during production, and will be particular useful when aligning electrodes that are not purely rectangular, such as those described above.

The transmitter and receiver layer may have common piezoelectric material.

The means acting as ground plane may be one ground plane for each transmitter and receiver layer, or some or all of the transmitter and receiver layers may share one common ground plane, or the transmitter and receiver layers may act as ground plane to each other. The means acting as ground plane is an electrically conducting material connected to ground or any fixed voltage potential. In one embodiment, the transmitter and receiver electrodes may constitute the ground plane themselves. This can be achieved by grounding the receiver electrodes when the transmitter electrodes are active and vice versa. The ground plane may be made of a metal, but other materials, such as a composite or a conducting glue, may be chosen to provide any desired acoustical and electrical properties. The ground plane may also be provided by applying a metal layer on one face of the piezoelectric material.

In one embodiment, the ground plane is comprised in a flexible circuit. In the embodiment mentioned above with transmitter and receiver electrodes arranged on each side of a flexible circuit, the flexible circuit may comprise a ground plane electrically isolated from the transmitter and receiver electrodes.

The transmitter layers and the receiver layers are arranged above each other, and the planes comprising the respective electrodes of each layer are parallel.

The longitudinal direction/axes of the electrodes of the transmitter layers and the receiver layers are rotated with respect to each other, in such a way that they are not parallel. This means that the angle between the longitudinal axes of the transmitter electrodes and the longitudinal axes of the receiver electrodes are different from zero, and thus that the projection of the electrodes to a common plane will intersect/overlap. This leads to a number of defined intersection points, hereafter denoted “pixels”, which may be read one at a time by activating the different transmitter and receiver electrodes sequentially.

The angle between the transmitter electrodes and the receiver electrodes are in one embodiment 90°. Any other angles between transmitter and receiver electrodes may be manufactured, depending on the specific applications or requirements for the transducer module.

The ultrasonic transducer according to the invention may comprise a number of transmitter and receiver layers with different configurations. All layers are arranged in a stacked manner above each other.

In one embodiment, the transducer module comprises a number of pairs of transmitter and receiver layers, the angle between the receiver electrodes and the transmitter electrodes being greater than zero within all pairs and different between at least two pairs of transmitter and receiver layers.

In another embodiment, the transducer module comprises one transmitter layer and at least two receiver layers, the angle between the electrodes of the receiver layers and the transmitter layer being different for at least two receiver layers.

Other numbers and arrangements of layers and electrode angles can be chosen according to the specific needs of a particular application.

The ultrasonic transducer module may be used for a number of applications. Examples of applications are:
Reading of codes. An example is the Data Matrix codes which are two-dimensional barcodes that can store from 1 to about 2,000 characters. The symbol is square or rectangular and can range from 0.001 inch per side up to 14 inches per side. The Data Matrix can be of Direct Part Marking type or marked on tags/labels by perforating process. The codes can be visible or covered by paint, dirt, contamination etc.
Non destructive testing. Non-destructive testing is the branch of engineering concerned with all methods of detecting and evaluating flaws in materials. The flaws may be cracks or inclusions in welds and castings, or variations in structural properties which can lead to loss of strength or failure in service.
Measurement of paint thickness.
Skin disease diagnostics/analysis of human skin/tissue. Other medical purpose.

The invention will now be described in more detail, by means of the accompanying figures.

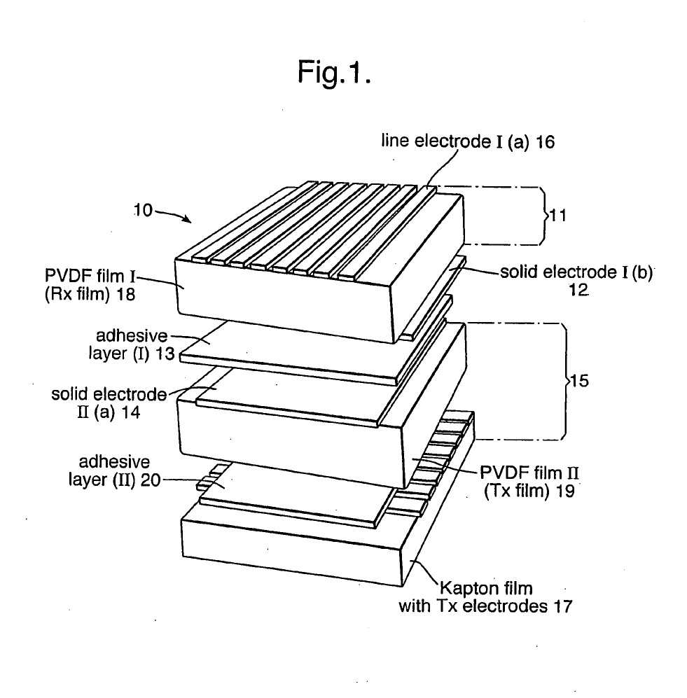

FIG. 1 shows a principle drawing of one embodiment of the invention.

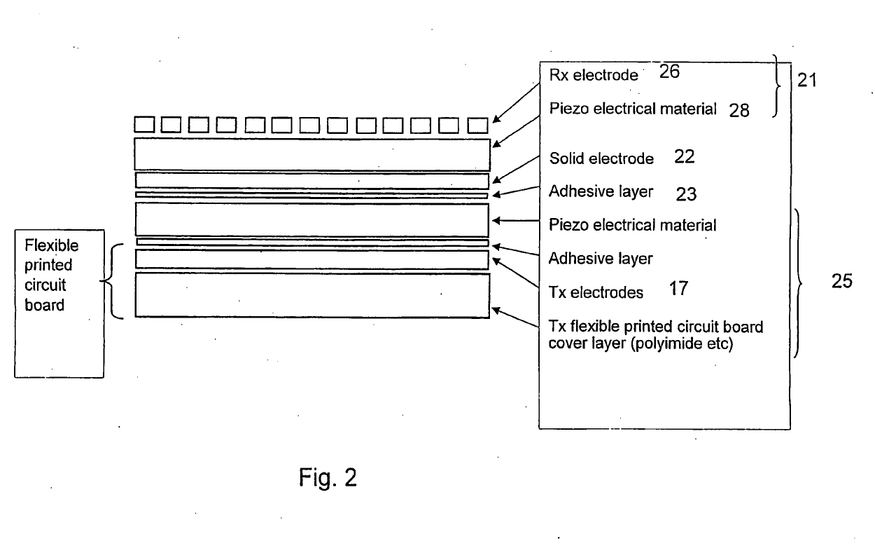

FIG. 2 illustrates an embodiment similar to the embodiment, but with only one ground plane.

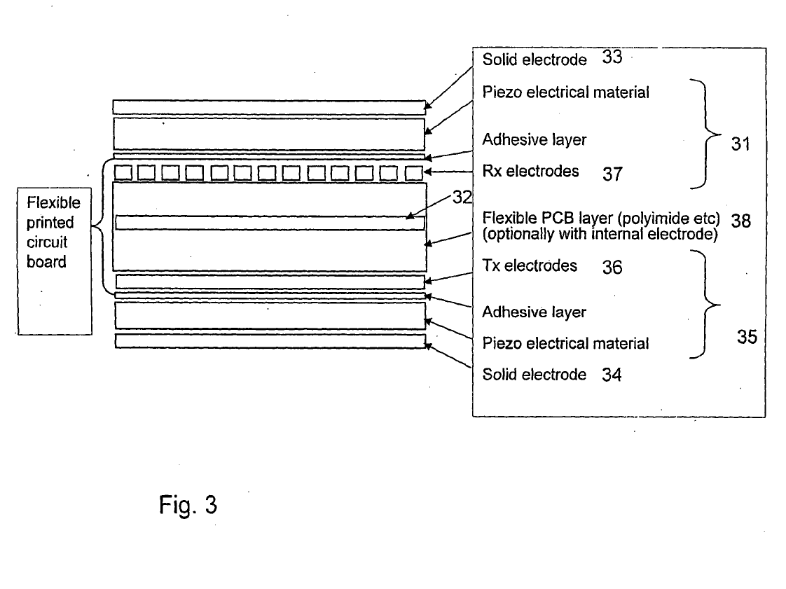

FIG. 3 illustrates another possible embodiment of the invention.

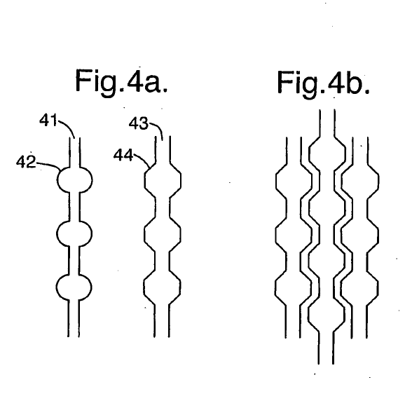

FIG. 4 shows examples of different shapes of the electrodes of a transducer module according to the invention.

FIG. 1 shows a principle drawing of one embodiment of the invention. The transducer module 10 comprises one transmitter layer 11, one receiver layer 15 and two ground planes 12, 14.

The receiver layer 11 comprises transmitter electrodes 16 and a piezoelectric material 18. The transmitter electrodes 16 are provided directly on the piezoelectric material 18 by means of e.g. lithography. The piezoelectric material 18 is for example a PVDF film. The longitudinal axes of the transmitter electrodes are arranged in parallel.

The transmitter layer 15 comprises receiver electrodes 17 on a flexible circuit (PCB) and a piezoelectric material 19. The receiver electrodes 17 on the flexible circuit are connected to the piezoelectric material 19 by means of an adhesive layer 20. The longitudinal axes of the receiver electrodes are arranged in parallel and perpendicular to the direction of the transmitter electrodes. This provides a number of overlapping intersections/pixels which constitutes signal points of the transducer.

The ground planes 12, 14 are provided directly on each of the piezoelectric materials 18, 19 by means of for example metal vaporization. An adhesive layer 13 is provided to connect the ground planes 13, 14 and thus the transmitter layer and the receiver layer to form the transducer module.

Such a module can have a variety of number of electrodes. A typical example comprises 16000 pixels.

FIG. 2 illustrates an embodiment similar to the embodiment of FIG. 1, but with only one ground plane. The receiver layer 21 and the transmitter layer 25 thus share a common ground plane 22, which may be provided directly on the piezoelectric material 28 of the receiver layer 21. The transmitter electrodes 17 is also in this embodiment produced on a flexible circuit, while the receiver electrodes 26 are produced directly on the piezoelectric material. The transmitter electrodes and receiver electrodes are arranged perpendicular to each other.

FIG. 3 shows an embodiment of the invention with a different configuration from the two previous figures. The receiver layer 31 and the transmitter layer 35 comprise respective receiver and transmitter electrodes 36, 37, produced on each side of the same flexible circuit 38. The flexible circuit may also comprise an internal ground plane 32 within the flexible circuit material, used for shielding between transmitter and receiver electrodes. Two piezoelectric materials, eg. PVDF films are glued to the electrodes 36, 37. There are also two ground planes 33, 34 connected to the surfaces of the piezoelectric materials which do not face the electrodes.

FIG. 4 shows examples of different shapes of the electrodes of a transducer module according to the invention. FIG. 4a shows two different electrode types, one 41 with circular widened portions 42 and the other 43 with hexagonal widened portions 44. FIG. 4b shows how using the electrode type 43 with hexagonal widened portions provides close packing and possible expanded intersection/pixel area.

1. Ultrasonic transducer module comprising at least one transmitter layer, at least one receiver layer and means acting as ground plane, wherein
the transmitter layer and the receiver layer comprise a number of elongated transmitter and receiver electrodes, the electrodes being arranged in parallel within each layer,
the transmitter layers and the receiver layers are parallel,
the electrodes of the receiver layers make an angle greater than zero with the electrodes of at least one of the transmitter layers,
and further wherein the transmitter electrodes constitute the ground plane for the receiver layer and the receiver electrodes constitute the ground plane for the transmitter layer.

2. Ultrasonic transducer module according to claim 1, wherein the electrodes of at least one of the transmitter layers or receiver layers are provided on a flexible circuit.

3. Ultrasonic transducer according to claim 1, wherein a transmitter electrode and a receiver electrode are provided on each side of a flexible circuit.

4. Ultrasonic transducer according to claim 1, wherein the electrodes of the transmitter layers are provided on a flexible circuit.

5. Ultrasonic transducer according to claim 1, wherein the electrodes of the receiver layers are provided on a flexible circuit.

6. Ultrasonic transducer according to claim 1, wherein the electrodes of the transmitter layers and the receiver layers are provided on two separate flexible circuits.

7. Ultrasonic transducer according to claim 1, wherein the angle between the longitudinal axes of receiver electrodes and the transmitter electrodes are 90°.

8. Ultrasonic transducer according to claim 1, wherein the receiver and transmitter electrodes have a rectangular shape.

9. Ultrasonic transducer according to claim 1, wherein the electrodes of at least one of the transmitter and receiver layers have elongated shape with wider sections regularly spaced from each other.

10. Ultrasonic transducer according to claim 1, wherein the electrodes of at least one of the transmitter and/or receiver layers comprises at least two sections, each section having its own electric connecting means.

11. Ultrasonic transducer according to claim 1, further comprising a number of pairs of transmitter and receiver layers, and that the angle between the receiver electrodes and the transmitter electrodes are different between at least two pairs of transmitter and receiver layers.

12. Ultrasonic transducer according to claim 1, further comprising one transmitter layer and at least two receiver layers, the angle of the electrodes of the receiver layers to the transmitter layer being different for at least two receiver layers.

13. (canceled)

14. (canceled)
